(19) United States
(12) Patent Application Publication
(10) Pub. No.: US 2025/0216794 A1
(43) Pub. Date: Jul. 3, 2025

(54) MIRROR DEVICE, FOR EXAMPLE FOR A MICROLITHOGRAPHIC PROJECTION EXPOSURE SYSTEM, AND METHOD FOR MEASURING THE TEMPERATURE OF A MIRROR

(71) Applicant: Carl Zeiss SMT GmbH, Oberkochen (DE)

(72) Inventors: Johannes LIPPERT, Buch am Wald (DE); Stefan HEMBACHER, Bobingen (DE); Matthias MANGER, Aalen (DE); Markus RAAB, Schillingsfuerst (DE); Andreas RABA, Niederschoenefeld (DE); Joern WEBER, Aalen (DE); Mirko BUECHSENSCHUETZ, Schweinfurt (DE)

(21) Appl. No.: 19/086,267

(22) Filed: Mar. 21, 2025

Related U.S. Application Data
(63) Continuation of application No. PCT/EP2023/075714, filed on Sep. 19, 2023.

(30) Foreign Application Priority Data
Sep. 28, 2022 (DE) 10 2022 210 244.4

(51) Int. Cl. G03F 7/00

(52) U.S. Cl. CPC G03F 7/70225; G03F 7/70266; G03F 7/70833; G03F 7/7085; G03F 7/70891

(57) ABSTRACT

A mirror device, such as for a microlithographic projection exposure system, comprises a mirror, a sensor unit and a control unit. The mirror comprises a mirror body and a reflective surface provided on the mirror body. The sensor unit comprises a sensor element and a signal path extending to the control unit to transmit a measurement signal representing the temperature of the sensor element to the control unit. The sensor element is provided in the substrate of the mirror body. The sensor element comprises a plurality of electrical conductor paths integrated in the substrate of the mirror body. The conductor paths form a plurality of crossing points electrically conductively connecting the conductor paths to one another.

### CROSS-REFERENCE TO RELATED APPLICATIONS

The present application is a continuation of, and claims benefit under 35 USC 120 to, international application No. PCT/EP2023/075714, filed Sep. 19, 2023, which claims benefit under 35 USC 119 of German Application No. 10 2022 210 244.4, filed Sep. 28, 2022. The entire disclosure of each of these applications is incorporated by reference herein.

### FIELD

The disclosure relates to a mirror device, for example for a microlithographic projection exposure apparatus, and to a method for measuring the temperature of a mirror.

### BACKGROUND

Microlithographic projection exposure apparatuses are utilized for the production of integrated circuits with particularly small structures. In some cases, a mask (=reticle) illuminated with very short-wave deep ultraviolet or extreme ultraviolet radiation (DUV or EUV radiation) is imaged onto a lithography object in order to transfer the mask structure to the lithography object.

The projection exposure apparatus comprises a plurality of mirrors at which the radiation is reflected. In general, the mirrors have a precisely defined shape and are precisely positioned in order that the imaging of the mask onto the lithography object is of sufficient quality.

During operation, the projection exposure apparatus can be subjected to influences which have an influence on the imaging quality. By way of example, if a thermal expansion leads to a change in the geometric shape of a mirror, then the wavefront of the radiation reflected at the mirror can change. For proper operation of the projection exposure apparatus, it is often helpful to have information concerning the temperature of the mirror. The temperature information can be used for example to control a heating unit or a cooling unit, such that the temperature of the mirror is kept at a constant value, or to suitably adjust the projection exposure apparatus after a temperature change. It is possible to record temperature measurement values using temperature sensors arranged in the vicinity of a mirror or to deduce the temperature of the mirror from variables indirectly related to the temperature of a mirror. For example, the temperature of the mirror can be deduced from the temperature of an atmosphere adjacent to the mirror. Such indirect measurement methods may not have a high accuracy.

### SUMMARY

The disclosure seeks to provide an improved mirror device and a method for measuring the temperature of a mirror.

In an aspect, the disclosure provides a mirror device suitable, for example, for a microlithographic projection exposure apparatus. The mirror device comprises a mirror, a sensor unit and a control unit. The mirror comprises a mirror body and a reflective surface formed on the mirror body. The sensor unit comprises a sensor element and a signal path extending to the control unit, in order to transmit a measurement signal representing the temperature of the sensor element to the control unit. The sensor element is formed in the substrate of the mirror body. The sensor element comprises a plurality of electrical conductor tracks integrated into the substrate of the mirror body. The conductor tracks form a plurality of crossing points. The conductor tracks are electrically conductively connected to one another at the crossing points.

The disclosure involves the concept of integrating a sensor element, the physical state of which changes depending on the temperature, directly into the substrate of the mirror body and of converting the state change into a measurement signal that can be transmitted to the control unit. The sensor element formed in the substrate of the mirror body can help enable a direct thermal coupling between the material of the mirror body and the sensor element. For example, transition losses can be avoided by the sensor element being formed as an integral part of the substrate of the mirror body. A change in the temperature of the mirror body directly affects the sensor element, such that a measurement signal can be obtained which is directly representative of the temperature of the mirror body in the region of the sensor element.

In one embodiment, the sensor element comprises an electrical conductor track integrated into the substrate of the mirror body. The electrical conductor track can be configured such that the electrical resistance changes depending on the temperature of the mirror body in the region of the conductor track. Suitable materials are known both in the form of positive temperature coefficient (PTC) thermistors and in the form of negative temperature coefficient (NTC) thermistors. The conductor track can include or consist of a material for which the relationship between the temperature and the electrical resistance is substantially proportional.

By applying an electrical signal to the conductor track, it is possible to measure the electrical resistance of the conductor track. The sensor unit can comprise a signal generator designed to apply an electrical signal to the conductor track. The sensor unit can comprise a closed electrical circuit extending from a first pole of the signal generator via the electrical conductor track to a second pole of the signal generator. A change in the electrical resistance of the conductor track can influence the electrical signal, such that a change in the temperature in the region of the electrical conductor track in the region of the mirror body can be deduced from a change in the electrical signal. The relationship between the temperature of the conductor track and the electrical resistance is known in advance or can be determined by calibration.

The conductor track can extend within the mirror body from an input end to an output end. Cables or comparable conductors suitable for transmitting an electrical signal can be connected to the input end and the output end and the electrical signal is transmitted via them between the signal generator and the conductor track. The conductor track can comprise a first section, in which the temperature dependence of the electrical resistance is low, and can comprise a second section, in which the temperature dependence of the electrical resistance is high. This can help make it possible to determine temperature measurement values for specific points of the mirror body in a targeted manner. The second section of the conductor track can be placed as a measurement point into the region of the mirror body in which the temperature might want to be measured, while the first section can form a kind of lead to the second section.

In one embodiment, the electrical conductor track has a smaller cross section in the second section than in the first section. Moreover, the first section and the second section can be a uniform conductor path including or consisting of a uniform electrically conductive material, for example. The electrical conductor track can comprise a plurality of first sections and second sections in this sense. It is also possible for the conductor track to include or consist of a different material in the second section than in the first section, wherein the material in the second section has an increased dependence of the electrical resistance on the temperature.

In an alternative embodiment, the electrical conductor track extends with constant cross section through the mirror body. In this case, the electrical conductor track can be regarded as a series connection of electrical resistances. A measurement signal obtained in this way can yield temperature information in the form of an average value over the length of the electrical conductor track.

The substrate of the mirror body can comprise regions which adjoin the electrical conductor tracks and in which the material of the mirror body is electrically nonconductive. For example, the electrical conductor track can be electrically insulated relative to the reflective surface. The electrical conductor track can be electrically insulated relative to a rear side of the mirror body situated opposite the reflective surface. In one embodiment, the electrical conductor track is surrounded all around by electrically nonconductive material of the mirror body.

The mirror body can comprise a plurality of electrical conductor tracks, each of which forms a sensor element within the meaning of the disclosure. From each of the conductor tracks a signal path can extend to the control unit. The mirror body can comprise a sensor layer extending parallel to the reflective surface, the conductor tracks being arranged within the sensor layer. The plurality of conductor tracks can help make it possible to obtain temperature information from different regions of the mirror body. Each of the conductor tracks can have one or more of the features mentioned above.

The conductor tracks can be electrically insulated from one another within the mirror body. Each of the conductor tracks can then makes it possible to obtain temperature information independent of the other conductor tracks. In one embodiment, provision is made of one or more crossing points between the conductor tracks, at which the conductor tracks are electrically conductively connected to one another. The number of crossing points can be greater than 10, such as greater than 50, for example greater than 100. Suitable interconnection of the electrical connection between the conductor tracks and the signal generator can help make it possible to conduct the electrical signal along different paths through the mirror body and in this way to obtain temperature information from different regions of the mirror body.

Each conductor track can comprise a switch which is arranged between the input end and the signal generator and which establishes an electrical connection between the conductor track and a signal generator in a first switching state and which disconnects the electrical connection in a second switching state. Furthermore, each conductor track can comprise a corresponding switch arranged between the output end and the signal generator. The switches can be controlled such that in each case one switch is closed at an input end and one switch is closed at an output end, while all other switches are open. This can result in an electrical path extending between the input end of a first conductor track and the output end of a second conductor track and also via exactly one crossing point between the first conductor track and the second conductor track. In one variant, there is more than one crossing point between the first conductor track and the second conductor track. The sensor unit can be designed such that the switch is changed over rapidly between the switching states. The time period for which a switching state is maintained can be for example between 1 ms and 50 ms, such as between 2 ms and 20 ms. Suitable evaluation of the different measurement signals can help make it possible to obtain temperature information for a multiplicity of regions of the mirror body. For a more accurate setting of the current paths, the conductor tracks can have further electrical/electronic components having current flow-dependent properties. Such components can have a reverse direction and a forward direction or exhibit a frequency dependence, for example. In this way, the local resolution of the temperature information can be improved and/or the evaluation can be facilitated.

Another possibility of obtaining locally resolved temperature information can include forming a plurality of measurement points within an individual conductor track, which measurement points can be controlled separately from one another. By way of example, the measurement points can be designed for electrical signals of different frequencies. In one embodiment, each measurement point is configured as a combination of a temperature-dependent measuring resistor and a band-stop filter configured in parallel therewith. The band-stop filter is at high impedance for a defined frequency and thus conducts an electrical signal of the relevant frequency through the measuring resistor. For other frequencies, the band-stop filter short-circuits the measuring resistor.

In one embodiment, the electrical conductor track comprises two different metals, which are electrically connected to one another at a connection point. On the basis of the Seebeck effect, the voltage between the two ends of the conductor track changes depending on the temperature at the connection point. The sensor element based on the two different metals forms a thermocouple in this way. The thermocouple can be configured such that, apart from the connection point, there is no transition between different metals within the mirror body. If there are further transitions between different metals within the mirror body, then a careful calibration of the thermocouple is used in order to be able to obtain temperature information for the connection point. The sensor unit can comprise a voltmeter, which measures the change in the electrical voltage between the ends of the conductor track.

In one embodiment, a first section of the conductor track and a second section of the conductor track are connected to two electrodes of a capacitor, the capacitance of which changes depending on the temperature. The capacitor can be configured such that heating of the mirror body causes a change in the electrode spacing. The changed capacitance can be measured and from that it is possible to derive a measurement signal representing the temperature of the mirror body in the region of the capacitor. In addition or as an alternative thereto, a dielectric having a temperature-dependent dielectric constant can be arranged between two electrodes of the capacitor.

The capacitor can be produced in the form of a local capacitance near the reflective surface. Alternatively, one electrode of the capacitor can be arranged near the reflective surface and the second electrode can be arranged on the rear side of the mirror body. In one embodiment, a continuous electrode surface constituting a common ground for a plurality of measurement electrodes is formed near the reflective surface. The measurement electrodes can be arranged at the rear side of the mirror body or can be accommodated within the mirror body.

The reflective surface of the mirror is usually formed by a layer system which is highly reflective for EUV radiation and/or DUV radiation. A multilayer coating can be involved, for example a multilayer coating having alternating layers of molybdenum and silicon. Using such a coating, it is possible to reflect approximately 70% of the incident EUV radiation. The term EUV radiation denotes electromagnetic radiation in the extreme ultraviolet spectral range with wavelengths of between 5 nm and 100 nm, for example with wavelengths of between 5 nm and 30 nm. DUV radiation is in the deep ultraviolet spectral range and has a wavelength of between 100 nm and 300 nm.

A sensor element according to the disclosure can be arranged between the reflective surface and a main body of the mirror body. During the production of a mirror according to the disclosure, a main body is usually taken as a starting point. In one variant, further layers are applied to the main body by way of additive manufacturing until the mirror has reached its final state. In a variant, the production of a mirror body comprises the step of joining the main body to a second partial body. In all cases, the layer system forming the reflective surface can be applied to the mirror body by coating.

If the sensor element comprises a conductor track, then a conductor track applied by a coating process can be involved. The body or partial body to which the conductor track can be applied can be electrically nonconductive. The conductor tracks can be produced by an electrically conductive material being applied along the conductor tracks. The regions between the conductor tracks can be filled with an electrically nonconductive material. A layer which is arranged between the reflective surface and the main body and in which the sensor element is arranged is referred to as a sensor layer. If the sensor element comprises further components, such as for example a material whose resistance changes in a temperature-dependent manner in the case of the resistance measurement, or the electrodes of a capacitor in the case of the capacitance measurement, or the transition between two different metals in the case of a thermocouple, then these components can likewise be applied by coating. All components of the sensor element can be arranged within the sensor layer. The sensor layer can be covered with a layer composed of an electrically nonconductive material. The further layer construction can be effected thereon. If the layer construction comprises a surface protection layer, then the sensor layer can be arranged between the reflective surface and the surface protection layer or between the surface protection layer and the main body.

If the mirror body comprises a main body and a partial body, wherein the reflective surface is applied to the partial body, then the sensor layer can be arranged between the reflective surface and the partial body. In other embodiments, the sensor layer is arranged between the main body and the partial body. A sensor element arranged between the reflective surface and a main body of the mirror body has independently inventive content, even without the sensor element comprising a plurality of electrical conductor tracks integrated into the substrate of the mirror body.

It is also possible for the sensor element to comprise a grating structure written into a transparent material of the mirror body. The grating structure can be configured such that it influences an incident light signal differently depending on the temperature, such that the temperature can be deduced from a reflected or transmitted portion of the light signal. In the event of a temperature change, the transparent material can be subject to a thermal expansion that is transferred to the grating structure. The change in the grating structure can be measured by way of suitable light signals. The sensor unit can comprise a signal generator, which sends a light signal into the transparent material of the mirror body and evaluates a portion of the light signal that is transmitted or reflected at the grating structure, in order to determine therefrom a measurement signal representing the temperature of the mirror body in the region of the grating structure. The measurement signal can be conducted as an electrical signal from the signal generator to the control unit of the mirror device. A sensor element comprising a grating structure written into a transparent material of the mirror body has independently inventive content, even without the sensor element comprising a plurality of electrical conductor tracks integrated into the substrate of the mirror body.

The grating structure can be a structure which was written into the transparent material of the mirror body using a laser, for example a femtosecond laser. The grating structure can be for example a periodic microstructure which reflects light wavelength-selectively. For example, the grating structure can form a fiber Bragg grating. If a light signal with a large bandwidth is guided to the grating structure, then, in general, only light of a very limited spectral width is reflected at the grating structure. The wavelength of the reflected portions of the light signal changes in the event of a thermal expansion of the grating structure.

In addition to the grating structure, an optical channel can be written into the transparent material of the mirror body, along which the light signal is guided to the grating structure. The optical channel can be formed by the material around the channel being processed using a laser such that the light signal is reflected. As a result of the processing using the laser, the material of the mirror body obtains a locally increased refractive index. The processed material forms a kind of wall around the channel, such that the optical channel acts like a light guide for the light signal. The light signal can be guided into the interior of the optical channel, such that the light signal propagates within the optical channel as far as the grating structure.

The grating structure then can act like a fiber Bragg grating within the optical channel. The optical channel can be provided with a plurality of grating structures which are spaced apart from one another in the longitudinal direction of the optical channel and which reflect different wavelengths of the light signal. Generally, only light of a very limited spectral width around the Bragg wavelength is reflected at each fiber Bragg grating. The other portions of the light continue on their path through the optical channel. Heating causes extension of the respective grating structures. On the basis of the wavelength of the light reflected at a fiber Bragg grating, it is possible to generate a measurement signal representing the temperature of the mirror body in the region of the fiber Bragg grating. The light guide can be provided with at least 3, such as at least 5, for example at least 10, grating structures. The grating structures can be arranged equidistantly with respect to one another in the light guide.

Instead of writing the optical channel into the transparent material of the mirror body, the optical channel can also be formed as a cavity within the mirror body. The cavity can extend as far as the region of the mirror body in which the grating structure is formed.

The cavity can be formed as a drilled hole extending from the edge of the mirror body right into the vicinity of the grating structure. It would also be possible for the cavity to be arranged at a joint between two components of the mirror body and for a depression formed in one or both components to be shaped by the joining of the components to form a closed channel.

A mirror device in which the sensor element is formed by a transparent optical channel provided with fiber Bragg grating has independent inventive content, even without the sensor element being formed in the substrate of the mirror body. The sensor element can also be inserted into a cavity of the mirror body in the form of a light guide provided with fiber Bragg gratings.

In order to minimize the thermal deformation of the mirror despite the heat that arises from the absorbed radiation, the mirror device can be equipped with a cooling system, which keeps the temperature of the mirror as constant as possible. The cooling system can comprise a plurality of cooling channels extending along the reflective surface through the mirror body. The cooling system can comprise a coolant reservoir, from which the cooling channels are supplied with a coolant, for example water. The fluid whose temperature is measured in order to deduce the temperature of the mirror body can be the coolant of the cooling system.

The temperature of the mirror body in the region of the reflective surface is of interest in many cases. The mirror body can therefore be configured such that the sensor element is arranged near the reflective surface. The distance between the sensor element and the reflective surface can be less than the distance between the sensor component and the rear side of the mirror body situated opposite the reflective surface, such as greater at least by a factor of 2, for example greater at least by a factor of 5.

If cooling channels are formed in the mirror body, then particularly the temperature in a region of the mirror body that is situated between the cooling channels and the reflective surface is of interest. The sensor layer therefore can be arranged in this region of the mirror body. The sensor element according to the disclosure can be arranged within the mirror body such that the distance between the reflective surface and the sensor element is less than the distance between the sensor element and the cooling channels.

A description is given below of embodiments of the disclosure in which the sensor element is formed by the material of the mirror body and in which a change in the properties of the material is determined and is used as a measure of the temperature. If the geometric shape of the mirror body changes owing to a temperature change, for example, then this can be detected using ultrasonic waves. For this purpose, ultrasonic waves are directed onto the material of the mirror body in order to excite an ultrasonic oscillation in the material. In order to obtain information about the temperature of the mirror body, it is possible to determine either the damping of the ultrasonic wave or the time duration until the ultrasonic wave emerges again from the mirror body. For example, reflections at interfaces of the mirror body can have an influence on the ultrasonic waves which correlates with the temperature and can therefore be used for generating a measurement signal. In addition or as an alternative thereto, the correlation with the temperature can also be derived from the fact that the speed of sound within the material of the mirror body changes depending on modulus of elasticity, Poisson's ratio and density. If the dependence of these variables on the temperature is known, then the temperature can be deduced from the speed of sound. In all cases, the relationship between the ultrasonic measurement values and the temperature can be determined as a model-based correlation.

Alternatively, inelastic light scattering can excite a sound wave in the material of the mirror body and/or in the material of a component integrated into the mirror body, such as an optical fiber, for example. For this purpose, laser light is guided onto the material of the mirror body and/or onto the material of the component integrated into the mirror body, with the result that an interaction between the optical waves and acoustic lattice oscillations is established (Brillouin scattering). This interaction can be used for extension and/or temperature measurement using the frequency detuning of the laser radiation being utilized as a measurement signal for obtaining information. By way of example, a continuous and a pulsed laser beam can be incoupled into the material of the mirror body and the measurement location of the associated temperature can be deduced from the propagation times of the pulses of the pulsed laser beam. Alternatively, it is also possible to utilize the Raman effect, which is based on the interaction of optical waves with the optical phonons instead of the acoustic phonons.

In a further variant, eddy currents are induced within an electrically conductive material of the mirror body by applying alternating magnetic fields. For this purpose, an electrically conductive layer can be introduced into a mirror body, which otherwise includes or consists of a nonconductive material. For example, a metallic layer within the layer construction of the reflective surface is conceivable. The eddy currents form an electromagnetic field that can be measured. The strength of the eddy currents and associated electromagnetic fields generally depends on the electrical resistance and the geometry of the mirror body. Choosing a suitable excitation frequency makes it possible to generate a corresponding measurement signal. The temperature dependence of the measurement signal results from the fact that the resistivity of the material of the mirror body changes in a temperature-dependent manner and the distance with respect to the measurement coil is changed owing to a thermal expansion of the mirror body.

The penetration depth of the eddy currents into the target depends on the frequency of the alternating magnetic field, inter alia. The following holds true:

δ=(2ρ/ω/μ)\hat{ }0.5

where δ denotes the standard penetration depth, ρ denotes the electrical resistivity, μ denotes the magnetic permeability and ω denotes the angular frequency of the excitation field. δ corresponds to the penetration depth at which the eddy current strength still corresponds to 36.8% of the value at the surface of the target. At a depth of 5δ, the relative eddy current strength amounts to only 0.7%. The penetration depth can thus be controlled by way of the excitation frequency. By measuring with different excitation frequencies, it is possible to assign a resistance measurement to a depth in the mirror body. This makes it possible to vary the depth at which the temperature is measured. In order to prevent magnetic field lines from emerging on the rear side of the target, if possible the thickness of the target should be greater than 5 δ. Thin electrically conductive measurement regions involve high frequencies as magnetic excitation field, for example frequencies of at least 1 MHz, such as at least 10 MHz, such as at least 100 MHz, for example at least 1 THz.

The measurement can be carried out using an excitation coil and a measurement coil. Both the excitation coil and the measurement coil can be embodied as a wound coil. The coils can be flat coils or cylindrical coils, each of which can be embodied with a core or without a core. The coils can be produced in a coating process and/or patterning process. The coils can be of monolayer or multilayer design.

The excitation coil and/or the measurement coil can be arranged within the mirror body and can form for example an integral part of a sensor layer of the mirror body. In alternative embodiments, the excitation coil and/or the measurement coil are/is arranged outside the mirror body, for example on the rear side of the mirror, on a separate frame near the rear side of the mirror, on a separate frame in the vicinity of the mirror or at the edge of the mirror. In one embodiment, the excitation coil is arranged as a separate component adjacent to the reflective surface, while the measurement coil is integrated in a sensor layer of the mirror body. The measurement coil can be produced by coating and patterning.

The disclosure also relates to a projection lens of a projection exposure apparatus, wherein a mask is imaged onto a lithography object by way of a plurality of mirror devices, wherein at least one of the mirror devices is configured as a mirror device according to the disclosure. The projection lens can comprise at least two, such as at least three, for example at least five, mirror devices according to the disclosure. The temperature measurement value obtained by the sensor unit according to the disclosure can be used in a control system of the projection lens in order to control an operating parameter of the projection lens. For example, the operating parameter can be controlled in a closed control loop using the temperature measurement value. The disclosure furthermore relates to a projection exposure apparatus comprising such a projection lens.

The disclosure also relates to a method for measuring the temperature of a mirror of a microlithographic projection exposure apparatus. The mirror comprises a mirror body and a reflective surface formed on the mirror body. A sensor element is formed in the substrate of the mirror body. A measurement signal representing the temperature of the sensor element is transmitted to a control system of the microlithographic projection exposure apparatus.

The disclosure encompasses developments of the method with features that are described in the context of the mirror device according to the disclosure. The disclosure encompasses developments of the mirror device with features that are described in the context of the method according to the disclosure.

### BRIEF DESCRIPTION OF THE DRAWINGS

The disclosure is described by way of example below on the basis of certain embodiments with reference to the accompanying drawings, in which:

FIG. 1 shows a schematic illustration of a projection exposure apparatus according to the disclosure;

FIG. 2 shows a schematic illustration of a mirror device according to the disclosure;

FIG. 3 shows a plan view of the mirror body from FIG. 2;

FIG. 4 shows a vertical section through the mirror body from FIG. 2;

FIG. 5 shows an enlarged detail from FIG. 4;

FIG. 6 shows one embodiment of a sensor element according to the disclosure;

FIGS. 7-8 show the view according to FIG. 6 in the case of an alternative embodiment of the disclosure;

FIG. 9 shows an alternative embodiment of a sensor element according to the disclosure;

FIG. 10 shows a fiber Bragg light guide from FIG. 9 in an enlarged illustration; and

FIG. 11 shows a variant with respect to FIG. 8.

### DETAILED DESCRIPTION

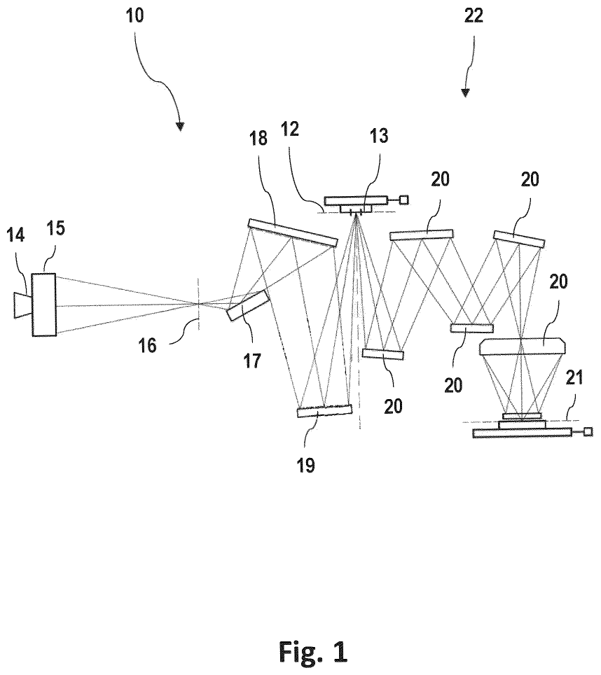

FIG. 1 schematically illustrates a microlithographic EUV projection exposure apparatus. The projection exposure apparatus comprises an illumination system 10 and a projection lens 22. An object field 13 in an object plane 12 is illuminated with the aid of the illumination system 10.

The illumination system 10 comprises an exposure radiation source 14, which emits electromagnetic radiation in the EUV range, i.e. with a wavelength of between 5 nm and 30 nm for example. The illumination radiation emerging from the exposure radiation source 14 is first focused into an intermediate focal plane 16 by way of a collector 15.

The illumination system 10 comprises a deflection mirror 17, by which the illumination radiation emitted by the exposure radiation source 14 is deflected onto a first facet mirror 18. A second facet mirror 19 is disposed downstream of the first facet mirror 18.

The individual facets of the first facet mirror 18 are imaged into the object field 13 by way of the second facet mirror 19.

With the aid of the projection lens 22, the object field 13 is imaged into an image plane 21 using a plurality of mirrors 20. Arranged in the object field 13 is a mask (also called reticle) which is imaged onto a light-sensitive layer of a wafer arranged in the image plane 21.

The various mirrors of the projection exposure apparatus at which the illumination radiation is reflected are configured as EUV mirrors. The EUV mirrors are provided with highly reflective coatings. Multilayer coatings can be involved, for example multilayer coatings having alternating layers of molybdenum and silicon. The EUV mirrors reflect approximately 70% of the incident EUV radiation. The approximately 30% that remains is absorbed and leads to heating of the EUV mirrors.

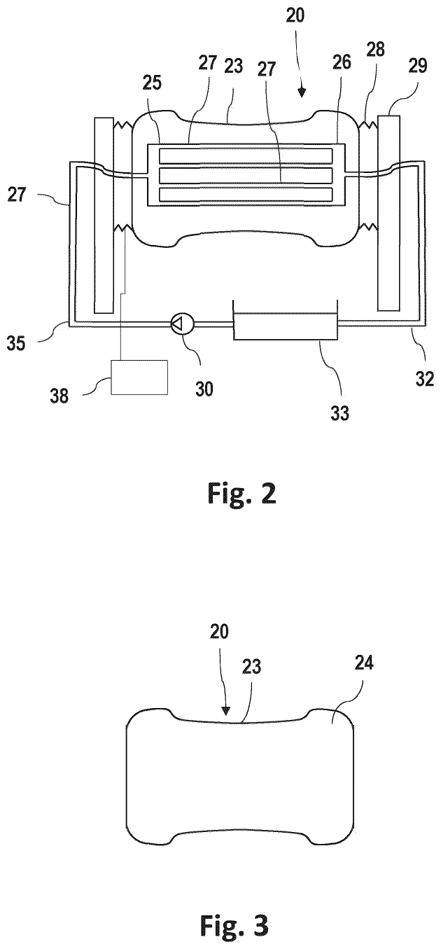

FIG. 2 shows a mirror device, in which a mirror body 23 of a mirror 20 is held on a frame structure 29 via actuators 28. The actuators 28 can be used to change the position of the mirror 20 relative to the frame structure 29 for the purpose of aligning and positioning the mirror 20 within the rigid body degrees of freedom. A reflective surface 24 at which incident EUV radiation is reflected is formed on the mirror body 23.

Cooling channels 27 are formed within the mirror body 23, and extend through the mirror body 23. The cooling channels 27 belong to a cooling system comprising a coolant reservoir 33 filled with a cooling liquid and a pump 30. Using the pump 30, cooling liquid is drawn from the coolant reservoir 33 and guided via a first connecting line 35 and an input manifold 25 to the cooling channels 27. The cooling liquid is guided back to the coolant reservoir 33 via an output manifold 26 adjoining the cooling channels and via a second connecting line 32. The cooling liquid absorbs heat resulting from the absorbed EUV radiation and dissipates this heat from the mirror body 23. At the transition between the frame structure 29 and the mirror body 23, the connecting lines 32, 35 are embodied as flexible hose lines in order not to impede the adjustment and alignment of the mirrors.

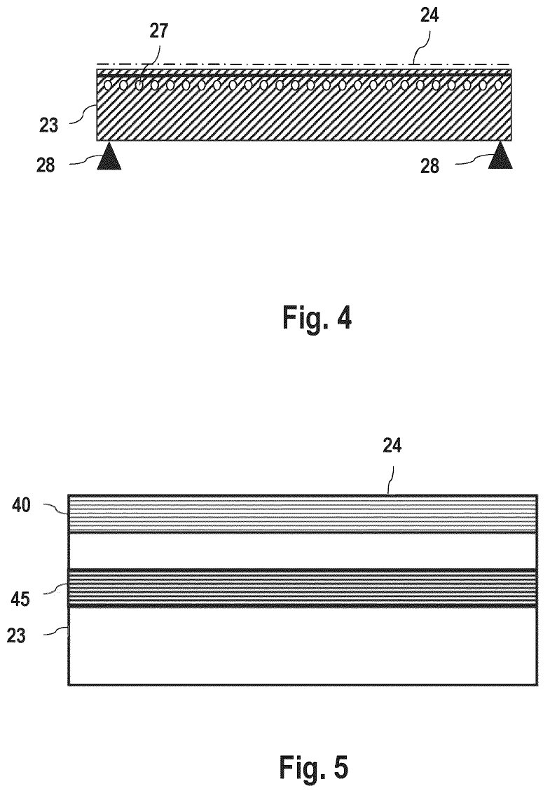

The cooling channels 27 are aligned along the horizontal extent of the mirror body 23. The cooling channels 27 extend rectilinearly and parallel to one another. The distance between the cooling channels 27 and the reflective surface 24 is constant over the length of the cooling channels 27 and is of the order of magnitude of 5 mm. In the schematic illustration in FIG. 2, only four cooling channels 27 parallel to one another are illustrated; in actual fact the number of cooling channels 27 is higher, as shown by the sectional illustration in FIG. 4. FIG. 3 illustrates a plan view of the reflective surface 24 of the mirror body 23. In the case of the projection exposure apparatus from FIG. 1, each of the mirrors 20 of the projection lens 22 can be configured as a mirror device in accordance with FIG. 2.

The mirror device comprises a control unit 38, which performs various control tasks for the mirror device. Inter alia, the control unit 38 controls the actuators 28 in order to bring the mirror body 23 into a desired position and orientation relative to the frame structure 29, and controls the pump 30 of the cooling system in order to adjust the cooling capacity. One of the input variables processed by the control unit 38 when determining the control commands for the actuators 28 is temperature measurement values regarding the temperature of the mirror body 23, which the control unit 38 obtains from a sensor unit. The temperature measurement values are used as a basis for controlling operating parameters of the mirror device, such as for example the actuators 28 or the cooling capacity of the cooling system or the capacity of a heating unit (not illustrated). The control can be effected within a closed control loop.

FIG. 5 shows an enlarged illustration of the construction of the mirror body 23 in the region between the cooling channels 27 and the reflective surface 24. The reflective surface 24 is formed by an optical layer system 40, in which alternating layers of molybdenum and silicon are stacked one above another. The optical layer system 40 is configured such that approximately 70% of the incident EUV radiation is reflected.

A sensor layer 45 is formed below the optical layer system 40 and determines the temperature of the mirror body 23 in the region of the sensor layer 45 and thus near the reflective surface 24. In the exemplary embodiment in accordance with FIG. 5, conductor tracks 41 are formed in the sensor layer 45, the conductor tracks including or consisting of a material whose resistance changes with temperature. Suitable materials are known both in the form of positive temperature coefficient (PTC) thermistors and in the form of negative temperature coefficient (NTC) thermistors. The conductor tracks 41 can include or consist of a material for which the relationship between the temperature and the electrical resistance is substantially proportional. The sensor layer 45 is produced by way of additive manufacturing, wherein the sensor layer 45 is fashioned such that electrically nonconductive material is applied between the conductor tracks 41. The top side of the sensor layer 45 can be smooth, i.e. free of elevations caused by the conductor tracks 41, in order that there is a good basis for the construction of the optical layer system 40.

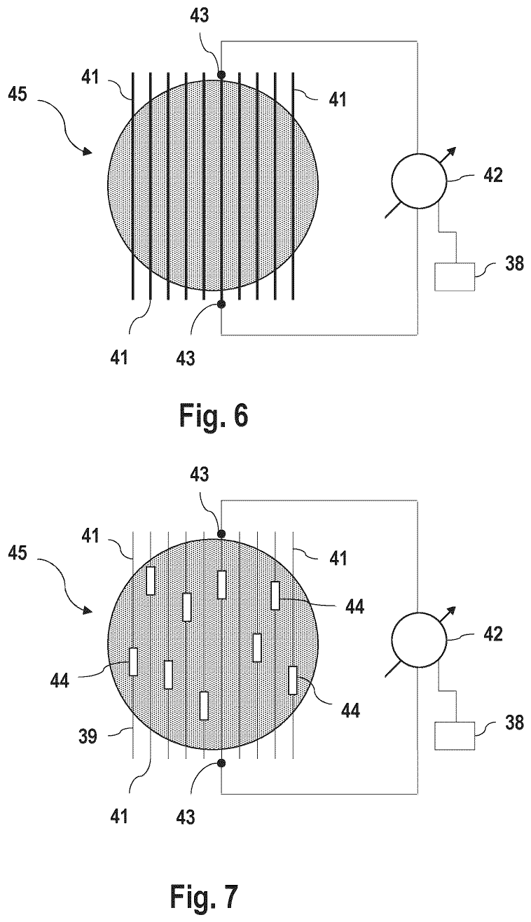

As shown by FIG. 6, the sensor layer 45 comprises a plurality of conductor tracks 41 extending parallel to one another and parallel to the reflective surface 24 through the mirror body 23. In the exemplary embodiment, the conductor tracks 41 include or consist of an NTC thermistor material over their entire length within the mirror body 23. The mirror device comprises a signal generator 42 designed to pass an electrical signal onto one of the conductor tracks 41 in order to obtain a measurement value of the electrical resistance of the conductor track 41. Since the relationship between temperature and electrical resistance of the conductor track 41 is known, the signal generator 42 can communicate a measurement signal in the form of a temperature measurement value to the control unit 38.

The signal generator 42 is connected to the conductor tracks 41 via a switching unit 43, illustrated schematically in FIG. 6, such that the resistance of each conductor track 41 can be measured individually depending on the state of the switching unit 43. The resistance of a conductor track 41 corresponds to an average value of the temperature of the mirror body 23 over the length of the conductor track 41.

In the case of the variant in accordance with FIG. 7, the conductor tracks 41 are configured as structured conductor tracks, the electrical properties of which change over the length of the conductor track 41. Each conductor track 41 comprises a measurement point 44 including or consisting of an NTC thermistor material. The other sections 39 of the conductor track 41 includes or consist of a material having a low electrical resistance and form a lead to the measurement point 44. In contrast to FIG. 6, the temperature information obtained using the signal generator 42 can be assigned to a specific position within the sensor layer 45 and thus to a specific region of the reflective surface 24.

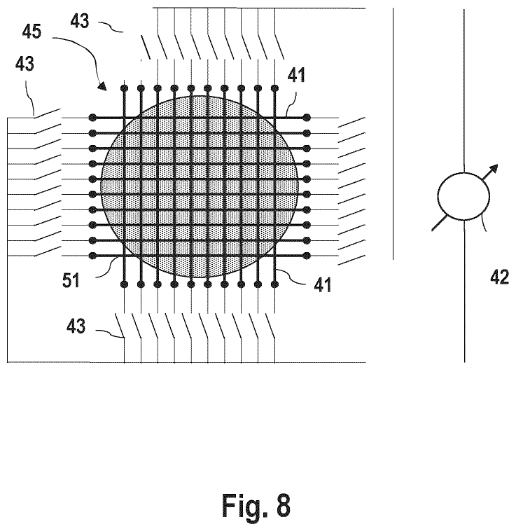

In FIG. 8, the sensor layer 45 comprises ten conductor tracks 41 aligned in a horizontal direction and ten conductor tracks 41 aligned in a vertical direction. The conductor tracks 41 are electrically conductively connected to one another at some of the crossing points 51, thus resulting in a plurality of branching points within the sensor layer 45. The switching unit 43 is configured such that respectively one input interface and one output interface are closed, while all other terminals of the conductor tracks 41 are not connected to the signal generator 42. In this way, it is possible to select a multiplicity of electrical paths along which the signal output by the signal generator 42 flows through the sensor layer 45. Locally resolved temperature measurement values can be obtained by successively measuring the resistance for a plurality of electrical paths and, if appropriate, forming suitable differences between the measurement values.

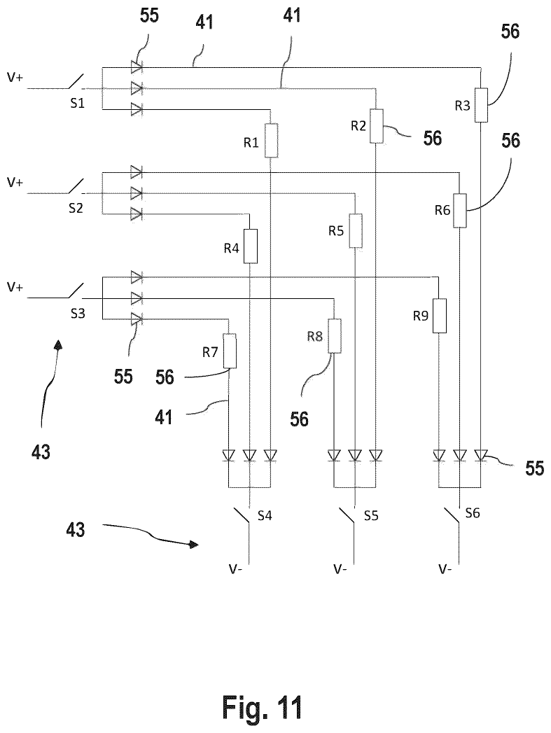

In the case of the variant shown in FIG. 11, three conductor tracks 41 are connected to each switch of the switching unit 43. If the switching unit 43 is actuated such that respectively one input interface and one output interface are closed, then there is exactly one electrical path that the measurement signal can take. Other paths otherwise possible for the electric current are blocked by diodes 55, which permit the electric current to pass only in one direction. Exactly one measurement point 56 is provided within each of the electrical paths. By actuating only three switches on the input side and three switches on the output side, temperature measurement values for nine different positions can be obtained in this way.

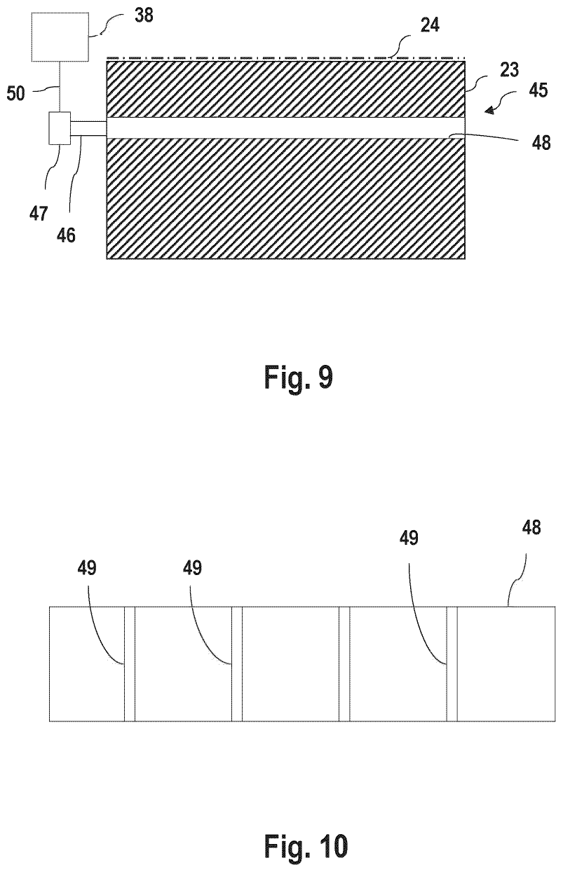

In the case of the alternative embodiment in accordance with FIG. 9, the mirror body 23 includes or consists of a material which is transparent to visible light. An optical channel 48 is written into the transparent material of the mirror body 23, and extends within the sensor layer 45 through the mirror body 23. The optical channel 48 can be formed by the material around the channel 48 being processed using a laser such that the material obtains a locally increased refractive index. The processed material forms a kind of wall around the optical channel 48, such that the optical channel 48 acts like a light guide. A light signal introduced into the interior of the optical channel 48 propagates in the optical channel 48 as in a light guide.

Grating structures in the form of fiber Bragg gratings 49 are written within the optical channel 48, these being produced by the same method as for the wall of the optical channel 48. The fiber Bragg gratings 49 are periodic microstructures which are written into the material of the mirror body 23 and which reflect light wavelength-selectively.

Within the optical channel 48, the fiber Bragg gratings 49 are arranged equidistantly with respect to one another. Each of the fiber Bragg gratings 49 reflects a different wavelength of the light.

If light with a large bandwidth is introduced into the light guide 46, then only light of a narrowly limited spectral width is reflected at each of the fiber Bragg gratings 49. The other portions of the light continue on their path through the light guide until a different wavelength of the light is reflected at the next fiber Bragg grating 49. Heating of the mirror body 23 causes extension of the fiber Bragg gratings 49, as a result of which the wavelength of the light reflected at the fiber Bragg grating 49 changes. On the basis of the wavelength of the reflected light, it is possible to generate a measurement signal representing the temperature in the region of the fiber Bragg grating 49. Suitable evaluation of the reflected light signals makes it possible to obtain temperature information for each of the fiber Bragg gratings 49.

The mirror device comprises a signal generator 47 coupled to the optical channel 48 via a light guide 46. A light signal generated by the signal generator 47 can be incoupled into the optical channel 48 via the light guide 46. From the reflected light portions, the signal generator 47 determines a temperature measurement value and communicates it to the control unit 38 via a signal path 50.

What is claimed is:

1. A mirror device, comprising:
a mirror comprising a mirror body and a reflective surface supported by the mirror body, the mirror body;
a plurality of electrical conductor tracks in the mirror body; and
a control unit,
wherein:
the plurality of electrical conductor tracks is connected to the control unit to transmit a measurement signal representing a temperature of the plurality of electrical conductor tracks to the control unit;
the plurality of electrical conductor tracks define a plurality of crossing points electrically conductively connecting the plurality conductor tracks to one another; and
for at least one of the electrical conductor tracks, the electrical conductor track comprises a first section and a second section, a temperature dependence of an electrical resistance of the first section being less than a temperature dependence of an electrical resistance of the second section.

2. The mirror device of claim 1, wherein, for each of the electrical conductor tracks, the electrical conductor track comprises a first section and a second section, a temperature dependence of an electrical resistance of the first section being less than a temperature dependence of an electrical resistance of second first section.

3. The mirror device of claim 1, wherein the mirror body comprises electrically nonconductive regions adjoining the electrical conductor tracks.

4. The mirror device of claim 1, further comprising a grating structure written into a transparent material of the mirror body.

5. The mirror device of claim 4, further comprising a signal generator configured to: i) send a light signal into the transparent material of the mirror body; and ii) evaluate a portion of the light signal that is transmitted or reflected at the grating structure to determine therefrom a measurement signal representing a temperature of the mirror body in a region of the grating structure.

6. The mirror device of claim 5, wherein the mirror body comprises an optical channel surrounding the grating structure.

7. The mirror device of claim 4, the mirror body comprises an optical channel surrounding the grating structure.

8. The mirror device of claim 1, wherein the mirror body comprises a sensor layer comprising at least one region extending parallel to the reflective surface, and the plurality of electrical conductor tracks are in the sensor layer.

9. The mirror device of claim 1, wherein the mirror body comprises a main body, and the plurality of electrical conductor tracks is arranged between the reflective surface and the main body of the mirror body.

10. The mirror device of claim 1, wherein the mirror body comprises a plurality of cooling channels, and the plurality of electrical conductor tracks is between the reflective surface and the cooling channels.

11. The mirror device of claim 1, wherein the mirror body comprises a sensor layer comprising at least one region extending parallel to the reflective surface, the plurality of electrical conductor tracks are in the sensor layer, and the mirror body comprises electrically nonconductive regions adjoining the electrical conductor tracks.

12. The mirror device of claim 1, wherein the mirror body comprises a main body, the plurality of electrical conductor tracks is arranged between the reflective surface and the main body of the mirror body, and the mirror body comprises electrically nonconductive regions adjoining the electrical conductor tracks.

13. The mirror device of claim 1, wherein the mirror body comprises a plurality of cooling channels, the plurality of electrical conductor tracks is between the reflective surface and the cooling channels, and the mirror body comprises electrically nonconductive regions adjoining the electrical conductor tracks.

14. A projection lens, comprising:
a plurality of mirror devices configured to image an object in an object field of the projection lens into an image field of the projection lens,
wherein, for at least one mirror device of the plurality of mirror devices, the at least one mirror device comprises:
a mirror comprising a mirror body and a reflective surface supported by the mirror body, the mirror body;
a plurality of electrical conductor tracks in the mirror body; and
a control unit, and
wherein:
the plurality of electrical conductor tracks is connected to the control unit to transmit a measurement signal representing a temperature of the plurality of electrical conductor tracks to the control unit;
the plurality of electrical conductor tracks define a plurality of crossing points electrically conductively connecting the plurality conductor tracks to one another; and
for at least one of the electrical conductor tracks, the electrical conductor track comprises a first section and a second section, a temperature dependence of an electrical resistance of the first section being less than a temperature dependence of an electrical resistance of the second section.

15. The projection lens of claim 14, wherein, for at least two of mirror devices of the plurality of mirror devices, each of the at least two mirror devices comprises:
a mirror comprising a mirror body and a reflective surface supported by the mirror body, the mirror body;
a plurality of electrical conductor tracks in the mirror body; and
a control unit, and
wherein:
the plurality of electrical conductor tracks is connected to the control unit to transmit a measurement signal representing a temperature of the plurality of electrical conductor tracks to the control unit;
the plurality of electrical conductor tracks define a plurality of crossing points electrically conductively connecting the plurality conductor tracks to one another; and
for at least one of the electrical conductor tracks, the electrical conductor track comprises a first section and a second section, a temperature dependence of an electrical resistance of the first section being less than a temperature dependence of an electrical resistance of the second section.

16. An apparatus, comprising:
an illumination system; and
a projection lens according to claim 14,
wherein the illumination system is configured to illuminate an object in the object plane.

17. The apparatus of claim 16, wherein, for at least two of mirror devices of the plurality of mirror devices, each of the at least two mirror devices comprises:
a mirror comprising a mirror body and a reflective surface supported by the mirror body, the mirror body;
a plurality of electrical conductor tracks in the mirror body; and
a control unit, and
wherein:
the plurality of electrical conductor tracks is connected to the control unit to transmit a measurement signal representing a temperature of the plurality of electrical conductor tracks to the control unit;
the plurality of electrical conductor tracks define a plurality of crossing points electrically conductively connecting the plurality conductor tracks to one another; and
for at least one of the electrical conductor tracks, the electrical conductor track comprises a first section and a second section, a temperature dependence of an electrical resistance of the first section being less than a temperature dependence of an electrical resistance of the second section.

18. A method of operation a microlithographic projection exposure apparatus comprising an illumination system and a projection lens, the projection lens comprising a plurality of mirror devices, the method comprising:
using the illumination system to illuminate an object in an object plane of the projection lens; and
using the plurality of mirror devices to image the illuminated object into an image plane of the projection lens,
wherein the projection lens is a projection lens according to claim 14.

19. The method of claim 18, wherein, for at least two of mirror devices of the plurality of mirror devices, each of the at least two mirror devices comprises:
a mirror comprising a mirror body and a reflective surface supported by the mirror body, the mirror body;
a plurality of electrical conductor tracks in the mirror body; and
a control unit, and
wherein:
the plurality of electrical conductor tracks is connected to the control unit to transmit a measurement signal representing a temperature of the plurality of electrical conductor tracks to the control unit;
the plurality of electrical conductor tracks define a plurality of crossing points electrically conductively connecting the plurality conductor tracks to one another; and
for at least one of the electrical conductor tracks, the electrical conductor track comprises a first section and a second section, a temperature dependence of an electrical resistance of the first section being less than a temperature dependence of an electrical resistance of the second section.

20. A method of measuring the temperature of a mirror of a microlithographic projection exposure apparatus, the mirror comprising a mirror body and a reflective surface supporting the mirror body, a plurality of electrical conductor tracks being in the mirror body, the plurality of conductor tracks defining a plurality of crossing points that electrically conductively connect the conductor tracks to one another, a conductor track comprising first and second sections, a temperature dependence of an electrical resistance of the first section being less than a temperature dependence of an electrical resistance of the second section, the method comprising:
transmitting a measurement signal representing a temperature of the plurality of conductor tracks to a control system of the microlithographic projection exposure apparatus.
